(19) United States
(12) Patent Application Publication
(10) Pub. No.: US 2026/0015718 A1
(43) Pub. Date: Jan. 15, 2026

(54) METHOD OF CONTROLLING VAPORIZATION SYSTEM, METHOD OF MANUFACTURING SEMICONDUCTOR DEVICE, VAPORIZATION SYSTEM, SUBSTRATE PROCESSING APPARATUS, AND RECORDING MEDIUM

(71) Applicant: KOKUSAI ELECTRIC CORPORATION, Tokyo (JP)

(72) Inventors: Shinya EBATA, Toyama-shi (JP); Kenichi ISHIGURO, Toyama-shi (JP)

(73) Assignee: KOKUSAI ELECTRIC CORPORATION, Tokyo (JP)

(21) Appl. No.: 19/337,463

(22) Filed: Sep. 23, 2025

Related U.S. Application Data
(63) Continuation of application No. PCT/JP2024/012791, filed on Mar. 28, 2024.

(30) Foreign Application Priority Data
Apr. 19, 2023 (JP) 2023-068702

(51) Int. Cl. C23C 16/448; C23C 16/44

(52) U.S. Cl. CPC C23C 16/448; C23C 16/4412

(57) ABSTRACT

A technique includes: (a) supplying a liquid precursor into a vaporization container; (b) regulating a pressure in the vaporization container to reduce the pressure at a time point when (a) is completed or after a first predetermined time has elapsed since the time point; (c) after (b), maintaining a state in which the regulation of the pressure in the vaporization container is stopped while vaporizing the liquid precursor; and (d) after (c), supplying a vaporized gas generated by vaporizing the liquid precursor in the vaporization container into a process container in which a substrate is processed.

### CROSS-REFERENCE TO RELATED APPLICATIONS

This application is a Bypass Continuation application of PCT International Application No. PCT/JP2024/012791, filed on Mar. 28, 2024, and designating the United States, the international application being based upon and claiming the benefit of priority from Japanese Patent Application No. 2023-068702, filed on Apr. 19, 2023, the entire content of which is incorporated herein by reference.

### TECHNICAL FIELD

The present disclosure relates to a method of controlling a vaporization system, a method of manufacturing a semiconductor device, a vaporization system, a substrate processing apparatus, and a recording medium.

### BACKGROUND

In the related art, a vaporization system that generates a vaporized gas by vaporizing a liquid precursor stored in a vaporization container, and a substrate processing apparatus that performs substrate processing using the generated vaporized gas, are disclosed.

When the liquid precursor stored in the vaporization container decreases, the vaporization container may be replenished with the liquid precursor. However, due to pressure fluctuations within the vaporization container that occur when the liquid precursor is injected into the vaporization container, incomplete vaporization of the liquid precursor may be likely to occur. The present disclosure provides a technique capable of suppressing incomplete vaporization of the liquid precursor that may occur due to the injection of the liquid precursor into the vaporization container.

### SUMMARY

According to embodiments of the present disclosure, there is provided a technique, including: (a) supplying a liquid precursor into a vaporization container; (b) regulating a pressure in the vaporization container to reduce the pressure at a time point when (a) is completed or after a first predetermined time has elapsed since the time point; (c) after (b), maintaining a state in which the regulation of the pressure in the vaporization container is stopped while vaporizing the liquid precursor; and (d) after (c), supplying a vaporized gas generated by vaporizing the liquid precursor in the vaporization container into a process container in which a substrate is processed.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, showing the portion of the process furnace 202 shown in a vertical sectional view.

FIG. 2 is a schematic configuration diagram of the vertical process furnace of the substrate processing apparatus suitably used in embodiments of the present disclosure, showing the portion of the process furnace 202 is shown in a sectional view taken along line L in FIG. 1.

FIG. 3 is a configuration diagram showing a vaporization system provided in the substrate processing apparatus suitably used in embodiments of the present disclosure.

FIG. 4 is a schematic configuration diagram of a controller 121 of the substrate processing apparatus suitably used in embodiments of the present disclosure, in which the control system of the controller 121 is shown in a block diagram.

FIG. 5 is a diagram showing a film formation sequence when performing a film formation process on a wafer in embodiments of the present disclosure.

FIG. 6 is a diagram showing the relationship between the passage of time and the pressure in the vaporization container in embodiments of the present disclosure.

FIG. 7 is a diagram showing the relationship between the passage of time and the pressure in the vaporization container in embodiments of the present disclosure.

FIG. 8 is a diagram showing the relationship between the passage of time and the pressure in the vaporization container in a comparative example of the present disclosure.

FIG. 9 is a configuration diagram showing a vaporization system provided in a substrate processing apparatus suitably used in embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

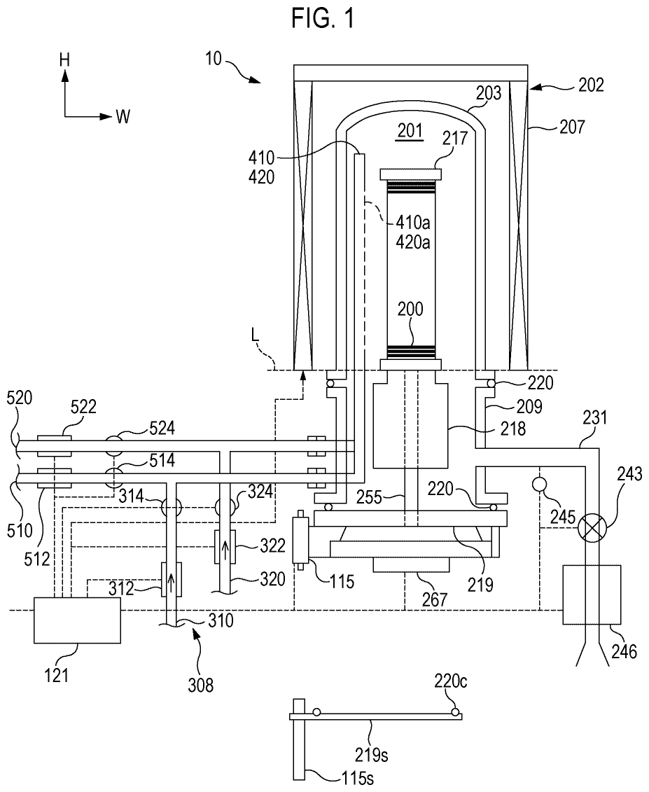

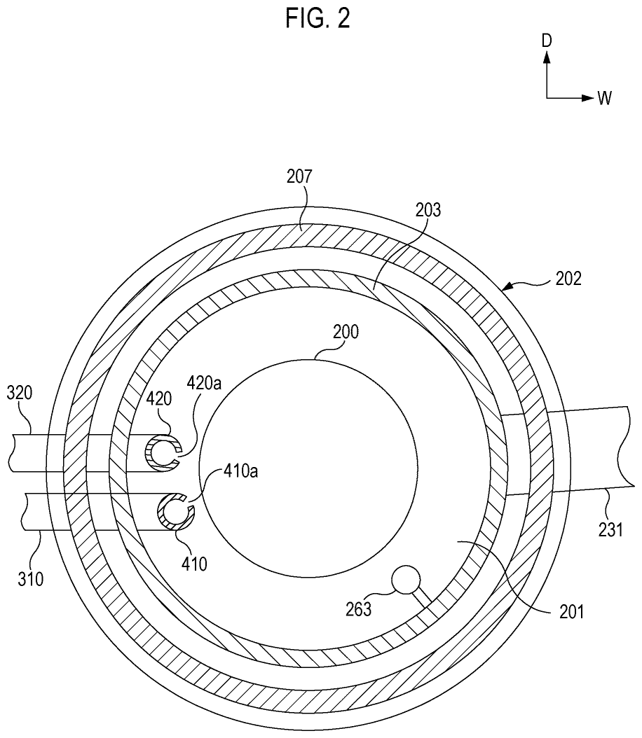

Embodiments of the present disclosure will be described below mainly with reference to FIGS. 1 to 6 and 8. Drawings used in the following description are schematic, and the dimensional relationships and ratios of respective elements shown in the drawings may not correspond to actual ones. Furthermore, the dimensional relationships and ratios of respective elements between multiple drawings may not correspond to each other.

### (1) Configuration of Substrate Processing Apparatus

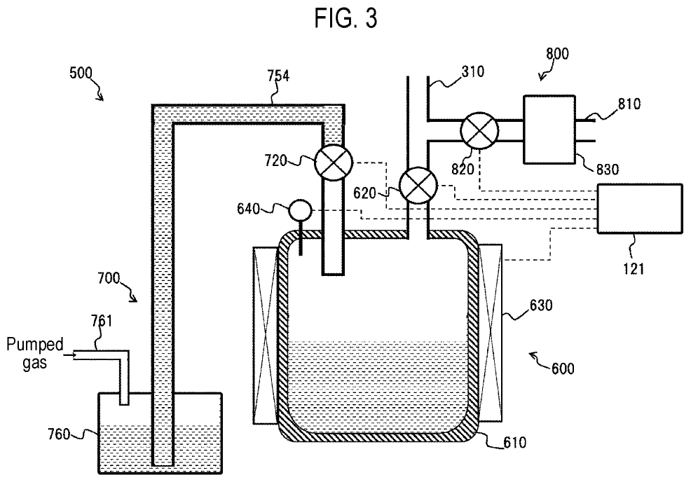

As shown in FIG. 1, a substrate processing apparatus 10 equipped with a vaporization system (see FIG. 3) described below includes a process furnace 202 for processing wafers 200 as substrates. The process furnace 202 includes a cylindrical heater 207 extending vertically within the apparatus. The heater 207 is supported by a heater base (not shown) serving as a holding plate. The heater 207 heats the interior of a process chamber 201 described below to a predetermined temperature.

Furthermore, a cylindrical process tube 203 serving as a process part is arranged inside the heater 207 concentrically with the heater 207. A process chamber 201 for processing a plurality of wafers 200 is formed inside the process tube 203. Specifically, a plurality of wafers 200 (e.g., 25 to 200 wafers) are stacked one above another on a boat 217 serving as a substrate support tool. The plurality of wafers 200 stacked on the boat 217 are arranged inside the process chamber 201. A cylindrical heat insulating cylinder 218 is arranged below the boat 217.

A cylindrical manifold 209 is arranged below the process tube 203 concentrically with the process tube 203. The upper end of the manifold 209 faces the lower end of the process tube 203. The manifold 209 supports the process tube 203 via an O-ring 220 serving as a sealing member.

Furthermore, nozzles 410 and 420 extending in the vertical direction are arranged in the process chamber 201 between the wall surface of the process tube 203 and the plurality of wafers 200 stacked on the boat 217. Furthermore, a plurality of supply holes 410a and 420a for supplying gases are formed in the nozzles 410 and 420, respectively, in the range where the supply holes 410a and 420a face the wafers 200 in the horizontal direction. As a result, the gases injected from the supply holes 410a and 420a flow toward the wafers 200.

Furthermore, the lower end portions of the nozzles 410 and 420 penetrate the side wall of the manifold 209, and the lower ends of the nozzles 410 and 420 protrude outside the manifold 209. Gas supply pipes 310 and 320 as gas supply lines are connected to the lower ends of the nozzles 410 and 420, respectively.

On the gas supply pipes 310 and 320, mass flow controllers (MFCs) 312 and 322 serving as flow rate controllers (flow rate control parts) and valves 314 and 324 serving as open/close valves are respectively provided sequentially from the upstream side in the flow direction of the gases flowing through the gas supply pipes 310 and 320 (hereinafter referred to as “gas flow direction”). Furthermore, the ends of gas supply pipes 510 and 520 serving as gas supply lines for supplying an inert gas are connected to the gas supply pipes 310 and 320 on the downstream side of the valves 314 and 324 in the gas flow direction. On the gas supply pipes 510 and 520, MFCs 512 and 522 and valves 514 and 524 are respectively provided in order from the upstream side in the flow direction of the gas flowing through the gas supply pipes 510 and 520.

A precursor gas serving as a processing gas generated by vaporizing a liquid precursor in a storage tank 610 (described later) is supplied from the gas supply pipe 310 to the process chamber 201 via the MFC 312, the valve 314, and the nozzle 410. A precursor gas supply system or a precursor gas supplier is composed of the gas supply pipe 310, the MFC 312, and the valve 314 (similarly, hereinafter, the “supply system” may be referred to as “supplier.”). The nozzle 410 may be included in the precursor gas supply system. Furthermore, the vaporization system 500 (described later) may be included in the precursor gas supply system. The precursor gas supply system may also be referred to as precursor supply system or vaporized gas supply system.

On the other hand, a reaction gas serving as a processing gas is supplied from the gas supply pipe 320 to the process chamber 201 via the MFC 322, the valve 324, and the nozzle 420.

When the reaction gas (reactant) is supplied from the gas supply pipe 320, a reaction gas supply system (reactant supply system) is mainly composed of the gas supply pipe 320, the MFC 322, and the valve 324. The nozzle 420 may be included in the reaction gas supply system. When the reaction gas is allowed to flow from the nozzle 420, the nozzle 420 may be referred to as reaction gas nozzle.

Furthermore, an inert gas is supplied from the gas supply pipes 510 and 520 to the process chamber 201 via the MFCs 512 and 522, the valves 514 and 524, and the nozzles 410 and 420.

An inert gas supply system is mainly composed of the gas supply pipes 510 and 520, the MFCs 512 and 522, and the valves 514 and 524.

Meanwhile, one end of an exhaust pipe 231 serving as an exhaust flow path for exhausting the atmosphere of the process chamber 201 is connected to the wall surface of the manifold 209. A pressure sensor 245 serving as a pressure detector (pressure detection part) for detecting the pressure in the process chamber 201 and an APC (Auto Pressure Controller) valve 243 serving as an exhaust valve (pressure regulator) are attached to the exhaust pipe 231. A vacuum pump 246 serving as an exhauster is attached to the end of the exhaust pipe 231.

The APC valve 243 is a valve configured to be able to exhaust and stop the exhaust of the process chamber 201 by being opened and closed while the vacuum pump 246 is operating, and further configured to be able to regulate the pressure in the process chamber 201 by being adjusted in the valve opening degree thereof based on pressure information detected by the pressure sensor 245 while the vacuum pump 246 is operating. An exhaust system is mainly composed of the exhaust pipe 231, the APC valve 243, and the pressure sensor 245. The vacuum pump 246 may be included in the exhaust system.

A seal cap 219 as a furnace opening cover that can airtightly close the lower end opening of the manifold 209 is provided below the manifold 209. The seal cap 219 is configured to abut against the lower end of the manifold 209 from below in the vertical direction via an O-ring 220. On the opposite side of the process chamber 201 from the seal cap 219, a rotator 267 that rotates a boat 217 (described later) is installed. A rotary shaft 255 of the rotator 267 is connected to the boat 217. The rotator 267 is configured to rotate the boat 217, thereby rotating the wafers 200.

The seal cap 219 is configured to be raised or lowered in the vertical direction by a boat elevator 115 serving as an elevating mechanism installed vertically outside the process tube 203. The boat elevator 115 is configured to be able to load and unload the boat 217 into and out of the process chamber 201 by raising and lowering the seal cap 219. The boat elevator 115 is configured as a transfer device that transfers the boat 217, i.e., the wafers 200, into and out of the process chamber 201. In addition, a shutter 219s serving as a furnace opening cover that can airtightly close the lower end opening of the manifold 209 via an O-ring 220c while the seal cap 219 is being lowered by the boat elevator 115 is provided below the manifold 209. The opening/closing operation of the shutter 219s is controlled by a shutter opening/closing mechanism 115s.

A temperature sensor 263 serving as a temperature detector is also arranged in the process chamber 201. The temperature in the process chamber 201 is set to a desired temperature distribution by adjusting the power supply to the heater 207 based on the temperature information detected by the temperature sensor 263. The temperature sensor 263 is provided along the inner wall of the process tube 203, just like the nozzles 410 and 420.

### [Vaporization System]

Next, the vaporization system 500 will be described using FIG. 3. The vaporization system 500 vaporizes a liquid precursor stored in a storage tank 610 to generate a vaporized gas as a precursor gas, and supplies the vaporized gas into the process chamber 201 via a gas supply pipe 310. The vaporization system 500 includes a vaporizer 600, a replenisher 700, and a pressure regulator 800, which will be described later. The vaporization system 500 may also be considered to include at least a part of the precursor gas supply system.

### [Vaporizer 600]

The vaporizer 600 includes a storage tank 610 as a vaporization container for storing a liquid precursor that will be vaporized into a precursor gas, a heater 630 as a heating part (heating device) that heats the storage tank 610 to vaporize the liquid precursor, and a pressure sensor 640 that detects the pressure in the storage tank 610.

The storage tank 610 is formed, for example, in a rectangular parallelepiped shape or a cylindrical shape. The storage space formed inside the storage tank 610 is a space sealed from the outside when the valves 620 and 720 are closed. The lower end side of the gas supply pipe 310 is connected to pass through the ceiling of the storage tank 610 so as to communicate with the inside of the storage space.

The liquid precursor is vaporized in the storage tank 610 in a state in which the valves 620 and 720 are closed, thereby filling the storage tank 610 with a vaporized gas. The vaporized gas thus filled is pumped to the gas supply pipe 310 by the pressure in the storage tank 610.

In the vaporizer 600 of these embodiments, other gases such as a carrier gas and the like are not supplied to the storage tank 610. Therefore, the pressure increase in the storage tank 610 is mainly caused by the generation of the vaporized gas due to the vaporization of the liquid precursor and the supply (replenishment) of the liquid precursor into the storage tank 610, which will be described later.

### [Replenisher 700]

The replenisher 700, which serves as a liquid precursor supply system, is a device that replenishes the storage tank 610 with a liquid precursor pumped from a replenishment tank 760. The replenisher 700 includes a liquid supply pipe 754 as a liquid precursor supply line through which the liquid precursor flows, and a valve 720 which is an open/close valve. The replenisher 700 may also include the replenishment tank 760 as a liquid precursor supply source. Furthermore, the valve 720 may also be configured so that in addition to the opening/closing operation (full opening/full closing operation), the flow rate (or pumping pressure) of the liquid precursor can be adjusted by controlling the opening degree of the valve 720 with the controller 121. The valve 720 is closed when the liquid precursor is not being replenished.

The liquid supply pipe 754 penetrates the ceiling of the storage tank 610, and one end thereof is connected so as to communicate with the inside of the storage tank 610. By opening the valve 720, the liquid precursor in the liquid supply pipe 754 is pumped into the storage tank 610. At this time, when the valve 620 is closed and the liquid precursor is pumped into the storage tank 610, which is a sealed space, the pressure in the storage tank 610 may rise rapidly.

The replenishment tank 760 is arranged outside the storage tank 610 and is connected to the other end of the liquid supply pipe 754. A pressure feed pipe 761 is connected to the upper portion of the replenishment tank 760. A pumped gas is sent from the pressure feed pipe 761 to the replenishment tank 760, and the liquid precursor stored in the replenishment tank 760 is pumped into the liquid supply pipe 754 by the pumping pressure in the replenishment tank 760.

The pressure in the replenishment tank 760 is greater than the pressure in the storage tank 610. For example, the pressure in the storage tank 610 is 100 Pa to 10,000 Pa, and the pumping pressure of the liquid from the replenishment tank 760 is 0.1 MPa to 10 MPa.

### [Pressure Regulator 800]

The pressure regulator 800 includes an exhaust pipe 810 as an exhaust line, one end of which is directly or indirectly connected to the storage tank 610, a valve 820, which is an open/close valve provided in the exhaust pipe 810, and an exhaust pump 830 as an exhaust device connected to the exhaust pipe 810 on the downstream side of the valve 820. In these embodiments, the exhaust pipe 810 is connected to the gas supply pipe 310 on the downstream side of the valve 620 and is connected so as to communicate with the interior of the storage tank 610 via the gas supply pipe 310. In this case, the valve 620 may also be considered to constitute the pressure regulator 800.

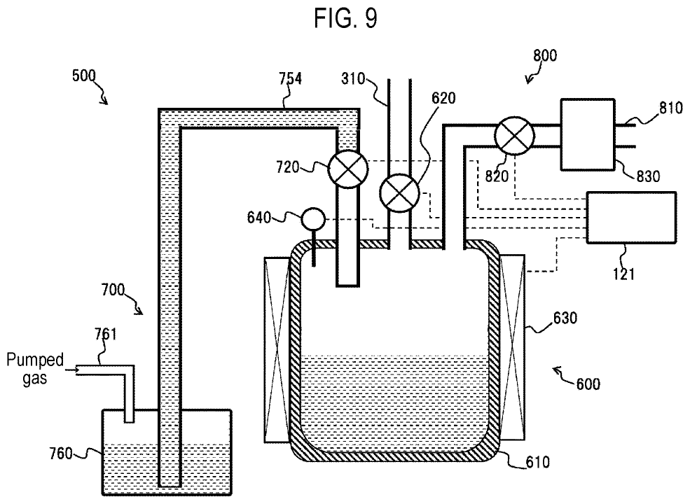

As another embodiment, as shown in FIG. 9, the exhaust pipe 810 may be installed so as to be directly connected to the storage tank 610 without passing through the gas supply pipe 310.

Furthermore, instead of providing the vacuum pump 830, the exhaust pipe 810 may be connected to the exhaust pipe 231 (on the downstream side of the APC valve 245), and the vacuum pump 246 may be used to exhaust the gas from the exhaust pipe 810. Moreover, instead of providing the vacuum pump 830, the exhaust pipe 810 may be connected to an exhaust line installed in a facility in which the substrate processing apparatus 10 is installed, and the exhaust pipe 810 may be used to exhaust the gas through the exhaust line.

Furthermore, the valve 820 may be configured so that in addition to the opening/closing operation (full opening/full closing operation), the flow rate (exhaust speed) of the exhausted gas can be adjusted by controlling the opening degree thereof with the controller 121. The valve 820 is closed when the pressure regulation is not performed in the storage tank 610, which will be described later.

Furthermore, in addition to the valve 820, an MFC configured to adjust the flow rate of the exhaust gas in the exhaust pipe 810 may be further provided on the exhaust pipe 810. The flow rate control by the MFC under the control of the controller 121 makes it possible to adjust the exhaust speed when regulating the pressure in the storage tank 610.

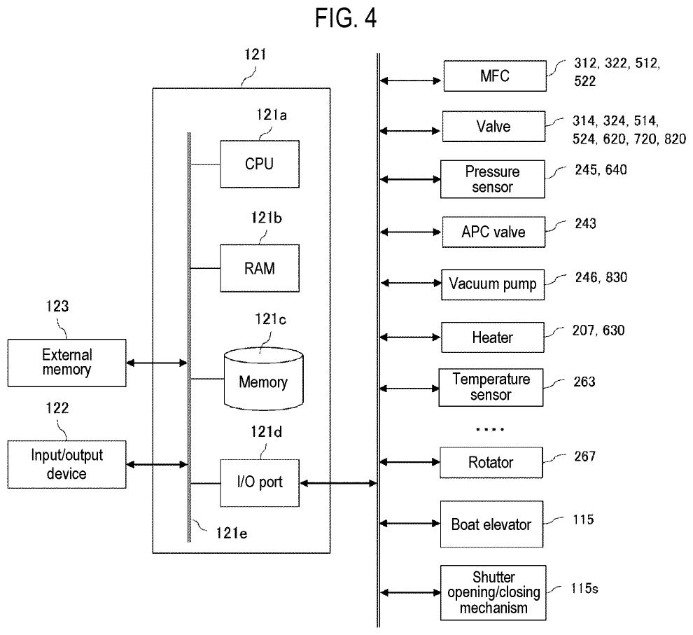

Next, the controller 121 provided in the substrate processing apparatus 10 will be described. As shown in FIG. 4, the controller 121 is configured as a computer including a CPU (Central Processing Unit) 121a, a RAM (Random Access Memory) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel, is connected to the controller 121.

The memory 121c is composed of, for example, a flash memory, an HDD (Hard Disk Drive), or the like. Various programs, such as a control program for controlling the operation of the substrate processing apparatus and a liquid precursor replenishment program (described later), and data for executing each program, are readably stored in the memory 121c. The RAM 121b is configured as a memory area (work area) in which programs and data read by the CPU 121a are temporarily held.

The I/O port 121d is connected to the MFCs 312, 322, 512 and 522, the valves 314, 324, 514, 524, 620, 720 and 820, the pressure sensors 245 and 640, the APC valve 243, the vacuum pumps 246 and 830, the temperature sensor 263, the heaters 207 and 630, the rotator 267, the boat elevator 115, the shutter opening/closing mechanism 115s, and the like.

The CPU 121a is configured to read the control program from the memory 121c and execute the control program, and is configured to read data from the memory 121c in response to the input of an operation command from the input/output device 122, etc.

The CPU 121a is configured to control, in accordance with the contents of the data thus read, the flow rate adjustment operation for various gases by the MFCs 312, 322, 512 and 522, the opening/closing operation of the valves 314, 324, 514, 524, 620, 720 and 820, the opening/closing operation of the APC valve 243, the pressure regulation operation by the APC valve 243 based on the pressure sensor 245, the opening/closing operation of the valves 620 and 820 based on the pressure sensor 640, the start and stop of the vacuum pumps 246 and 830, the temperature adjustment operation of the heater 207 based on the temperature sensor 263, the rotation and rotation speed adjustment operation of the boat 217 by the rotator 267, the raising and lowering operation of the boat 217 by the boat elevator 115, and the opening/closing operation of the shutter 219s by the shutter opening/closing mechanism 115s. In addition to the controller 121, another controller configured to be able to control the above-mentioned controlled elements constituting the vaporization system 500 may be installed.

The controller 121 can be configured by installing a program stored in an external memory (e.g., a magnetic disk such as a magnetic tape or a hard disk, an optical disk such as a CD or a DVD, or a semiconductor memory such as a USB memory or a memory card) 123 into a computer.

The memory 121c and the external memory 123 are configured as computer-readable recording media. Hereinafter, these will be collectively and simply referred to as recording medium. When the term recording medium is used in this specification, it may include a case of solely including the memory 121c, a case of solely including the external memory 123, or a case of including both. The program (program product) may be provided to the computer using a communication means such as the Internet or a dedicated line, without using the external memory 123.

### (2) Substrate Processing Process

Next, a substrate processing method in which a substrate is processed using the substrate processing apparatus 10 will be described as a process of manufacturing a semiconductor device. Furthermore, a method for controlling the vaporization system 500 in which a liquid precursor is replenished into the storage tank 610 will be described as a process of processing a substrate. The operation of each part of the substrate processing apparatus 10 is controlled by the controller 121.

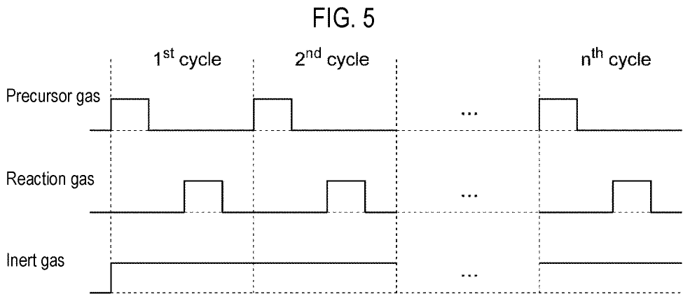

First, an example of a sequence for forming a film on a wafer 200 using the substrate processing apparatus 10 will be described with reference to FIG. 5. In these embodiments, the process chamber 201 accommodating a plurality of wafers 200 in a stacked state is heated to a predetermined temperature. Then, a precursor gas supply step of supplying a precursor gas containing a predetermined element into the process chamber 201 through the supply holes 410a of the nozzle 410 and a reaction gas supply step of supplying a reaction gas through the supply holes 420a of the nozzle 420 are performed a predetermined number of times (n times where n is an integer equal to or greater than 1). In this manner, a film containing the predetermined element is formed on the wafer 200. The predetermined number of times (n times) referred to here corresponds to one batch process in the film formation process and is set in advance.

### [Stacking and Loading]

First, a plurality of wafers 200 are stacked on the boat 217. The shutter 219s is moved by the shutter opening/closing mechanism 115s, thereby opening the lower end opening of the manifold 209. Then, as shown in FIG. 1, the boat 217 loaded with the plurality of wafers 200 is lifted by the boat elevator 115 and loaded into the process chamber 201. In this state, the seal cap 219 seals the lower end of the manifold 209.

### [Pressure Regulation and Temperature Adjustment]

Next, the process chamber 201 is exhausted by the vacuum pump 246 to a desired pressure (vacuum level). At this time, the pressure in the process chamber 201 is measured by the pressure sensor 245, and the APC valve 243 is feedback-controlled based on the measured pressure information (pressure regulation). The vacuum pump 246 remains in a constantly operating state until at least the processing of the wafers 200 is completed.

The process chamber 201 is heated to a desired temperature by the heater 207. The heating of the process chamber 201 by the heater 207 continues at least until the processing of the wafers 200 is completed.

Furthermore, the boat 217 and the wafers 200 are rotated by the rotator 267. The rotation of the boat 217 and the wafers 200 by the rotator 267 continues at least until the processing of the wafers 200 is completed.

### [Film Formation Process (Example of Substrate Processing)]

### [Precursor Gas Supply Step]

Next, the valves 314 and 620 are opened, and the vaporized precursor gas in the storage tank 610 is supplied into the process chamber 201 via the gas supply pipe 310. The precursor gas may be one or more gases obtained by vaporizing a liquid precursor in the storage tank 610. The valve 820 of the pressure regulator 800 is always closed unless the liquid precursor replenishment step described below is being performed.

Here, the storage tank 610 and the stored liquid precursor are heated by the heater 630, and the heated liquid precursor is vaporized to generate a precursor gas (vaporized gas). Immediately before the supply of the precursor gas to the process chamber 201 is started, the valve 620 is closed, and the storage tank 610 is filled with the precursor gas. The pressure in the storage tank 610 decreases while the precursor gas is being supplied (i.e., while the valves 314 and 620 are open), and increases due to the vaporization of the liquid precursor while the supply of the precursor gas is stopped (i.e., while the valves 314 and 620 are closed).

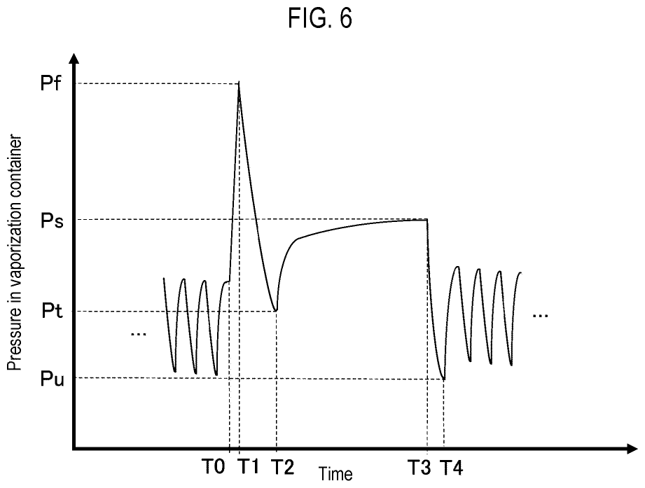

FIG. 6 shows the change in pressure in the storage tank 610 over time in these embodiments. For example, in the change in pressure before time point TO shown in FIG. 6, it is shown that a decrease in pressure due to the supply of the precursor gas and an increase in pressure due to the cessation of the supply of the precursor gas occur a predetermined number of times (n times) during one batch process in the film formation process. By repeating the vaporization and supply of the liquid precursor one or more times in this manner, the liquid precursor in the storage tank 610 is consumed. In these embodiments, the liquid precursor is replenished into the storage tank 610 (a replenishment step) for every plurality of batch processes. However, the liquid precursor replenishment step may be performed for each batch process.

The flow rate of the precursor gas supplied from the storage tank 610 is adjusted by the MFC 312. The precursor gas is supplied from the supply holes 410a of the nozzle 410 to the process chamber 201. At the same time, the valve 514 is opened to allow a carrier gas to flow into the gas supply pipe 510. The flow rate of the carrier gas is adjusted by the MFC 512. The carrier gas is supplied from the supply holes 410a of the nozzle 410 together with the precursor gas into the process chamber 201 and is exhausted from the exhaust pipe 231.

Furthermore, in order to prevent the precursor gas from entering the nozzle 420, the valve 524 is opened to allow the carrier gas to flow into the gas supply pipe 520. The carrier gas is supplied to the process chamber 201 via the gas supply pipe 520 and the nozzle 420, and is exhausted from the exhaust pipe 231.

At this time, the APC valve 243 is adjusted to set the pressure in the process chamber 201 to, for example, a pressure in a range of 1 to 1000 Pa. In this specification, for example, when a numerical range is stated as 1 to 1000 Pa, it means 1 Pa or more and 1000 Pa or less. In other words, the numerical range includes 1 Pa and 1000 Pa. The same applies to other numerical ranges stated in this specification.

The supply flow rate of the precursor gas controlled by the MFC 312 is, for example, within a range of 10 to 2000 sccm, preferably 50 to 1000 sccm, and more preferably 100 to 500 sccm. The time per cycle for supplying the precursor gas to the wafer 200 is, for example, within a range of 1 to 60 seconds. The heater 207 is controlled so that the temperature of the wafer 200 is, for example, within a range of 400 to 600 degrees C.

When the precursor gas is supplied to the process chamber 201 under the above-mentioned conditions, a layer containing the predetermined element contained in the precursor gas is formed on the outermost surface of the wafer 200.

The inert gas may be, for example, a nitrogen (N₂) gas, or a rare gas such as an argon (Ar) gas, a helium (He) gas, a neon (Ne) gas, a xenon (Xe) gas or the like. One or more of these gases may be used as the inert gas. This also applies to the respective steps described below.

Furthermore, the precursor gas may be a gas containing a predetermined element including a semiconductor element such as silicon (Si) and a metal element such as titanium (Ti), zirconium (Zr), hafnium (Hf), tantalum (Ta), aluminum (Al), molybdenum (Mo) or tungsten (W), which remain in a liquid state (i.e., as a liquid precursor) at the room temperature and the atmospheric pressure. The precursor gas can be obtained by vaporizing the liquid precursors for these gases in the storage tank 610.

For example, liquid precursors as Si-containing precursors including: halosilane precursor gases such as a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane (Si₂Cl₆) gas, an octachlorotrisilane (Si₃Cl₈) gas, a 1,2-bis(trichlorosilyl) ethane ((SiCl₃)₂C₂H₄) gas, a bis(trichlorosilyl) methane ((SiCl₃)₂CH₂) gas, a 1,1,2,2-tetrachloro-1,2-dimethyldisilane ((CH₃)₂Si₂Cl₄) gas, a 1,2-dichloro-1,1,2,2-tetramethyldisilane ((CH₃)₄Si₂Cl₂) gas, a 1-monochloro-1,1,2,2,2-pentamethyldisilane ((CH₃)₅Si₂Cl) gas, a trifluorosilane (SiHF₃) gas, a tetrafluorosilane (SiF₄) gas, a tribromosilane (SiHBr₃) gas, a tetrabromosilane (SiBr₄) gas, and the like; other inorganic silane precursor gases such as a trisilane (Si₃H₈) gas, a tetrasilane (Si₄H₁₀) gas, a pentasilane (Si₅H₁₂) gas, a hexasilane (Si₆H₁₄) gas, and the like; various aminosilane precursor gases such as a tetrakisdimethylaminosilane (Si[N(CH₃)₂]₄) gas, a trisdimethylaminosilane (Si[N(CH₃)₂]₃H) gas, a bisdiethylaminosilane (Si[N(C₂H₅)₂]₂H₂) gas, a bis-tert-butylaminosilane (SiH₂[NH(C₄H₉)]₂) gas, and the like; and other organic silane precursor gases such as 1,4-disilabutane (Si₂C₂H₁₀) gas, and the like may be used.

Furthermore, for example, liquid precursors including Ti-containing precursors such as a tetrakis(dimethylamino) titanium (Ti[N(CH₃)₂]₄) gas and a titanium tetrachloride (TiCl₄) gas, Hf-containing precursors such as a tetrakis(ethylmethylamino) hafnium (Hf[N(C₂H₅)(CH₃)]₄) gas and a hafnium tetrachloride (HfCl₄) gas, Zr-containing precursors such as a tetrakis(ethylmethylamino) zirconium (Zr[N(C₂H₅) CH₃)]₄) gas and the like, Al-containing precursors such as trimethylaluminum (Al(CH₃)₃) gas and the like, and Ta-containing precursors such as a tetraethoxytantalum (Ta(OC₂H₅)₄) gas, a trisethylmethylamino-tert-butyliminotantalum (Ta[NC(CH₃)₃][N(C₂H₅) CH₃]₃) gas and a pentaethoxytantalum (Ta(OC₂H₅)₅) gas may be used.

### [Residual Gas Removal Step]

After the layer containing the predetermined element is formed, the valves 314 and 620 are closed to stop the supply of the precursor gas. At this time, the APC valve 243 remains open, and the vacuum pump 246 exhausts the process chamber 201 to remove the precursor gas either unreacted or contributed to the formation of the layer containing the predetermined element, which remains in the process chamber 201. The valves 514 and 524 remain open to maintain the supply of the carrier gas to the process chamber 201. The carrier gas acts as a purge gas, enhancing the effect of removing the precursor gas either unreacted or contributed to the formation of the layer containing the predetermined element, which remains in the process chamber 201.

### [Reaction Gas Supply Step]

After removing the residual gas from the process chamber 201, the valve 324 is opened to allow a reaction gas to flow into the gas supply pipe 320. The reaction gas may be, for example, an oxygen-containing gas (oxidizing gas or oxidizing agent) that contains oxygen (O) and acts as a reactant that reacts with the predetermined element contained in the precursor gas. The oxygen-containing gas may be, for example, an oxygen (O₂) gas, an ozone (O₃) gas, a plasma-excited O₂ gas (O₂*), a mixed gas containing an O₂ gas and a hydrogen (H₂) gas, a water vapor (H₂O gas), a hydrogen peroxide (H₂O₂) gas, a nitrous oxide (N₂O) gas, a nitric oxide (NO) gas, a nitrogen dioxide (NO₂) gas, a carbon monoxide (CO) gas, a carbon dioxide (CO₂) gas, or the like. One or more of these gases may be used as the reaction gas.

The flow rate of the reaction gas is adjusted by the MFC 322. The reaction gas is supplied from the supply holes 420a of the nozzle 420 to the wafers 200 in the process chamber 201 and is exhausted from the exhaust pipe 231. That is, the wafers 200 are exposed to the reaction gas.

At this time, the valve 524 is opened to allow a carrier gas to flow into the gas supply pipe 520. The flow rate of the carrier gas is adjusted by the MFC 522. The carrier gas is supplied into the process chamber 201 together with the reaction gas and is then exhausted from the exhaust pipe 231. At this time, in order to prevent the reaction gas from entering the nozzle 410, the valve 514 is opened to allow the carrier gas to flow into the gas supply pipe 510. The carrier gas is supplied into the process chamber 201 via the gas supply pipe 510 and the nozzle 410, and is then exhausted from the exhaust pipe 231.

At this time, the APC valve 243 is appropriately adjusted to set the pressure in the process chamber 201 to, for example, a pressure in a range of 1 to 1000 Pa. The supply flow rate of the reaction gas controlled by the MFC 322 is set to, for example, a flow rate in a range of 5 to 40 slm, preferably 5 to 30 slm, and more preferably 10 to 20 slm. The time per cycle for supplying the reaction gas to the wafers 200 is set to, for example, a time in a range of 1 to 60 seconds. Other processing conditions are the same as those in the precursor gas supply step described above.

When an oxygen-containing gas is supplied as the reaction gas to the process chamber 201 under the above-described conditions, the reaction gas reacts with at least a portion of the layer containing the predetermined element formed on the wafer 200 in the precursor gas supply step, oxidizing the layer containing the predetermined element and forming an oxide layer containing the predetermined element and O. In other words, the layer containing the predetermined element is modified into an oxide layer containing the predetermined element.

### [Residual Gas Removal Step]

After the oxide layer is formed, the valve 324 is closed to stop the supply of the reaction gas. Then, using the same processing procedure as that of the residual gas removal step after the precursor gas supply step, the reaction gas or reaction by-products either unreacted or contributed to the formation of the oxide layer, which remain in the process chamber 201, are removed from the inside of the process chamber 201.

The cycle of sequentially performing the vaporization step, the precursor gas supply step, the residual gas removal step, the reaction gas supply step, and the residual gas removal step described above is performed a predetermined number of times (n times). By performing the plurality of steps a predetermined number of times in one batch process as described above, an oxide film is formed by stacking oxide layers on the wafer 200.

In this specification, the batch process may refer to a process in which the cycle of sequentially performing the precursor gas supply step, the residual gas removal step, the reaction gas supply step, and the residual gas removal step is performed a predetermined number of times (n times) to form a film of a predetermined thickness on the wafer 200. Thus, a film of a predetermined thickness is formed on the wafer 200 in one batch process.

### [Exhaust and Pressure Regulation]

After the film of a predetermined thickness is formed on the wafer 200 and the residual gas removal step is completed, the valves 514 and 524 are opened to supply a carrier gas to the process chamber 201 from the gas supply pipes 310 and 320, respectively, and exhaust the carrier gas from the exhaust pipe 231. The carrier gas acts as a purge gas, removing the gases and by-products remaining in the process chamber 201 from the inside of the process chamber 201. The atmosphere in the process chamber 201 is then replaced with the carrier gas, and the pressure in the process chamber 201 is returned to the atmospheric pressure (atmospheric pressure restoration).

### [Unloading and Taking-Out]

Then, the seal cap 219 is lowered by the boat elevator 115, the lower end of the manifold 209 is opened, and the processed wafers 200 supported on the boat 217 are unloaded from the lower end of the manifold 209 to the outside of the process tube 203.

After the wafers 200 are unloaded, the shutter 219s is moved to seal the lower end opening of the manifold 209. After being unloaded to the outside of the process tube 203, the processed wafers 200 are taken out from the boat 217. In these embodiments, the wafers 200 are loaded into and unloaded from the process tube 203 (process chamber 201) for each batch.

After the wafers 200 on which the film of a predetermined thickness has been formed through each process (step) is taken out as described above, if a film is to be formed on other wafers 200, the “stacking and loading,” “pressure regulation and temperature adjustment,” “film formation process,” “exhaust and pressure regulation,” and “unloading and taking out” are performed again. In other words, a batch process is performed again on wafers 200. The one batch process in this specification may also be considered to be a series of processes from “stacking and loading” to “unloading and taking-out.”

By the above-described film formation process, an oxide film containing a predetermined element contained in the precursor gas can be formed on the wafer 200. For example, using the above-described precursor gas, oxide films such as a titanium oxide film (TiO film), a zirconium oxide film (ZrO film), a hafnium oxide film (HfO film), a tantalum oxide film (TaO film), an aluminum oxide film (AlO film), a molybdenum oxide film (MoO film), and a tungsten oxide film (WO film) can be formed. Furthermore, by using a nitrogen-containing gas (nitriding gas or nitriding agent) instead of the oxygen-containing gas as the reaction gas, nitride films such as a titanium nitride film (TiN film), a zirconium nitride film (ZrN film), a hafnium nitride film (HfN film), a tantalum nitride film (TaN film), an aluminum nitride film (AlN film), a molybdenum nitride film (MON film), and a tungsten nitride film (WN film) can also be formed.

### [Liquid Precursor Replenishment Process]

After the precursor gas supply step for one batch process is completed, the storage tank 610 is replenished with a liquid precursor (replenishment process). The replenishment process is performed after the precursor gas supply step for one batch process is completed and the valves 314 and 620 are closed, and before the precursor gas supply step for the next batch process started and the valves 314 and 620 are opened. The replenishment process may be performed simultaneously with other steps of one batch process, or may be performed simultaneously with other steps of another batch process. Furthermore, in these embodiments, the replenishment process is performed for each batch. However, as described above, the replenishment process may also be performed once for multiple batches.

In these embodiments, in both the film formation process and the replenishment process, a state is maintained in which the heating by the heater 630 is controlled so that at least one selected from the group of the storage tank 610 and the stored liquid precursor reaches a predetermined temperature.

### (Step A: Liquid Precursor Supply Step)

After the precursor gas supply step is completed, the valve 720 is opened while the valve 620 is closed, and the liquid precursor in the liquid supply pipe 754 is pumped into the storage tank 610. By opening the valve 720 for a predetermined time and then closing the valve 720, a predetermined amount of liquid precursor is supplied (replenished) into the storage tank 610. As described above, when the valve 620 is closed and the liquid precursor is pumped into the storage tank 610, which is a sealed space, the pressure in the storage tank 610 may rise suddenly. As an example, FIG. 6 shows that the pressure in the storage tank 610 rises to a pressure Pf when the supply of the liquid precursor begins at time point TO and stops at time point T1.

Here, the pressure in the storage tank 610 at time point T1 becomes high, making it more likely that incomplete vaporization of the liquid precursor will occur. In particular, if the pressure rises to a value exceeding the saturated vapor pressure of the liquid precursor (specifically, the saturated vapor pressure at the temperature of the liquid precursor at that time point, which holds true hereinafter), the possibility of incomplete vaporization of the liquid precursor increases. There is also a possibility that a part of the vaporized gas in the storage tank 610 will be liquefied. If tiny droplets generated by incomplete vaporization flow into the process chamber 201 together with the precursor gas during the precursor gas supply step, they may adhere to the surface of the wafer 200, causing a decrease in product quality.

Therefore, in these embodiments, the pressure in the storage tank 610 is regulated in step B.

### (Step B: First Pressure Regulation Step)

After step A is completed, the valve 314 is closed, and the valves 620 and 820 are opened to exhaust the atmosphere in the storage tank 610 through the exhaust pipe 810, and pressure regulation is performed to reduce the pressure in the storage tank 610. The vacuum pump 830 remains operating at least while this step is being performed.

In these embodiments, as shown in the example of FIG. 6, pressure regulation is started at the time point (i.e., time point T1) when step A is completed or immediately thereafter, and pressure regulation is performed for a predetermined time (i.e., a first pressure regulation time or a second predetermined time). That is, the pressure regulation is performed from time point T1 to time point T2. By the pressure regulation, the pressure in the storage tank 610 is reduced to a pressure Pt which is a first predetermined pressure. At time point T2, the valves 620 and 820 are closed, thereby terminating this step (i.e., pressure regulation).

In this step, the possibility of incomplete vaporization of the liquid precursor can be reduced by reducing the pressure in the storage tank 610. In particular, it is preferable that the pressure Pt after pressure reduction is less than the saturated vapor pressure of the liquid precursor. By reducing the pressure in the storage tank 610 to a level less than the saturated vapor pressure, the possibility of incomplete vaporization of the liquid precursor can be significantly reduced.

The pressure regulation in this step is not limited to being terminated after being performed for a predetermined time as described above, but may be terminated based on the timing when the pressure in the storage tank 610 detected by the pressure sensor 640 becomes equal to or lower than a predetermined pressure (e.g., when the predetermined pressure is reached). In this case as well, the predetermined pressure is preferably set to a pressure lower than the saturated vapor pressure of the liquid precursor.

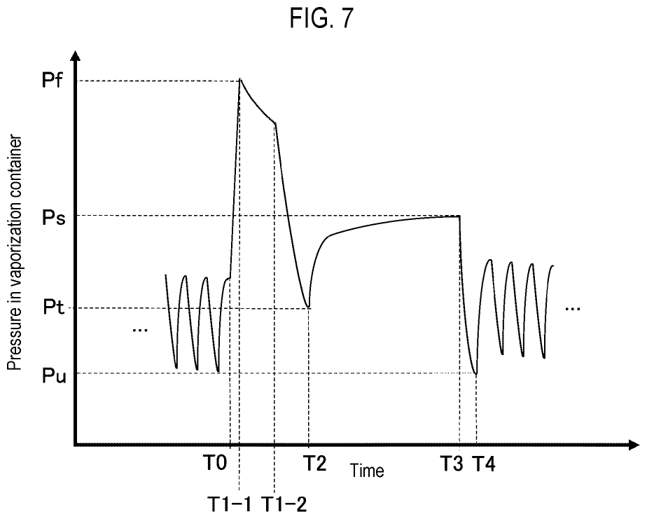

The timing for starting this step is not limited to the time point when step A is completed or immediately thereafter as in the example shown in FIG. 6, but may be the time (time point T1-2) when a predetermined time (i.e., a first predetermined time) has elapsed from the time point when step A is completed (time point T1-1) as in the example shown in FIG. 7. By performing the pressure regulation after a certain time interval has elapsed since the completion of step A in this way, it is possible to prevent tiny droplets and the like that may have been generated in the storage tank 610, from adhering to the inside of the gas supply pipe 310 and causing corrosion or the like during the pressure regulation.

The first predetermined time (i.e., the time from time point T1-1 to time point T1-2) is preferably shorter than the time needed for the pressure stabilization step (step C) described below (i.e., the time from time point T2 to time point T3). If the first predetermined time is longer than the time needed for the pressure stabilization step, the period from time point T1-1 to time point T1-2, during which incomplete vaporization is likely to occur, becomes longer, and the effect of this step of suppressing incomplete vaporization may not be fully achieved.

### (Step C: Pressure Stabilization Step)

After step B is completed, the valve 620 is closed to seal the storage tank 610. The liquid precursor is heated and vaporized in the sealed storage tank 610, thereby increasing (restoring) the pressure in the storage tank 610.

By ensuring that this step lasts for a sufficient period of time, the temperature of the liquid precursor in the storage tank 610 can be stabilized, and the pressure in the storage tank 610 can be increased to a pressure Ps close to the saturated vapor pressure of the liquid precursor at the stable temperature.

This step is terminated based on the timing at which the execution of the next batch process is started. For example, this step is terminated at a timing that is earlier by the time needed to execute steps D and E, which will be described later, than the timing at which the precursor gas supply step in the next batch process is started.

More specifically, for example, this step is terminated at a timing that is earlier by the aforementioned amount of time than the start time of the precursor gas supply step in the next batch process, which has been set in advance, or the start time of the precursor gas supply step in the next batch process, which has been instructed by the controller 121 from the user.

Furthermore, this step may also be continued at least until the rate of change of the pressure value in the storage tank 610 (i.e., the slope of the change in the pressure value over time) becomes equal to or less than a predetermined value.

Furthermore, this step may be continued for at least a predetermined time (i.e., a third predetermined time). The predetermined time is set to a time needed for the rate of change of the pressure value to become sufficiently small, which has been obtained, for example, by prior experiments or the like.

This step may be continued until the pressure value in the storage tank 610 rises to a predetermined pressure (i.e., a second predetermined pressure), which is set in advance. The predetermined pressure is set to a pressure obtained, for example, by prior experiments or the like, at which the rate of change of the pressure value is sufficiently small.

### (Step D: Second Pressure Regulation Step)

After step C is completed, as a previous step for the precursor gas supply step in the next batch process, similar to step B, the atmosphere in the storage tank 610 is exhausted through exhaust pipe 810 while closing the valve 314, and pressure regulation is performed to reduce the pressure in the storage tank 610. The vacuum pump 830 remains operating at least while this step is being performed.

In these embodiments, as shown in the example of FIG. 6, the pressure regulation is started at a time point when step C is completed (i.e., time point T3) or immediately thereafter. The pressure regulation is performed for a predetermined time (i.e., a second pressure regulation time or a fourth predetermined time). That is, the pressure regulation is performed from time point T3 to time point T4. By the pressure regulation, the pressure in the storage tank 610 is reduced to a pressure Pu. This step is terminated by closing the valves 620 and 820 at time point T4.

Here, the time needed to perform step B is longer than the time needed to perform step D. Since the pressure Pf in the storage tank 610 at the time point when step B is started is higher than the pressure Ps at the time point when step D is started, the pressure in the storage tank 610 can be reliably reduced to a desired pressure by lengthening the time needed to reduce the pressure in step B. For example, each step is performed such that the time Tb for performing step B and the time Td for performing step D satisfy the relationship 1<Tb/Td≤20.

Furthermore, by adjusting the opening degree of the valve 820, the exhaust speed for the storage tank 610 in step B may be made slower than the exhaust speed for the storage tank 610 in step D. By adjusting the exhaust speed in this manner, it becomes easier to control the pressure in the storage tank 610 in step B so that the pressure does not drop excessively.

In steps B and D, the opening degree of the valve 820 may be adjusted to make the exhaust speed for the storage tank 610 in step B slower than the exhaust speed for the storage tank 610 in step D. By adjusting the exhaust speed in this manner, it is possible to prevent the pressure in the storage tank 610 from excessively decreasing in step B, and to prevent the liquid precursor from being rapidly vaporized, discharged, and consumed. The exhaust speed may be adjusted by an MFC further provided in the exhaust pipe 810.

### (Step E: Pressure Increasing Step)

After step D is completed, similar to step C, the valve 620 is closed to seal the storage tank 610. By heating and vaporizing the liquid precursor in the sealed storage tank 610, the pressure in the storage tank 610 is increased (restored) to a pressure that allows the needed amount of precursor gas to be supplied in the precursor gas supply step.

After this step, the valves 314 and 620 are opened to start a precursor gas supply step in the next batch process.

(3) Comparison with Comparative Example

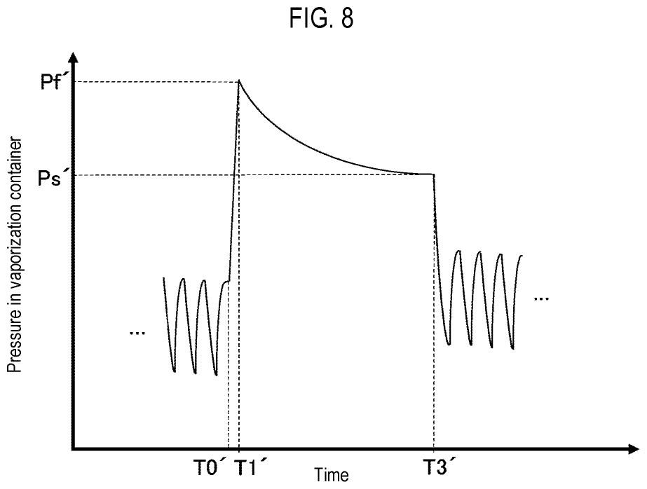

Now, as a comparative example of these embodiments, a case where steps B and D are not performed will be described. FIG. 8 shows an example of the change in pressure in the storage tank 610 over time in the comparative example.

In the comparative example, after the pressure in the storage tank 610 rises to a pressure Pf in step A, the valve 620 remains closed from time point T1′ to time point T3′ without performing pressure regulation. During this time, the pressure in the storage tank 610 decreases toward the saturated vapor pressure of the liquid precursor and stabilizes at a pressure Ps′. However, in the comparative example, while the pressure is changed in a decreasing direction, the pressure exceeds the saturated vapor pressure, and the state in which incomplete vaporization is likely to occur continues. Therefore, when the precursor gas supply step in the next batch process is started after time point T3′, there is a high possibility that mist of the liquid precursor generated by incomplete vaporization will be supplied into the process chamber 201 along with the precursor gas.

On the other hand, in the embodiments of the present disclosure, as shown in FIG. 6, in step B, the pressure in the storage tank 610 is reduced to a pressure lower than the saturated vapor pressure of the liquid precursor. As a result, in step C, the pressure changes in a direction increasing toward the saturated vapor pressure and stabilizes. In this way, in the embodiments of the present disclosure, by increasing the pressure and bringing it closer to saturation, it is possible to stabilize the pressure while maintaining a state in which incomplete vaporization of the liquid precursor is unlikely to occur.

Furthermore, in the embodiments of the present disclosure, in step D, as a previous step for the precursor gas supply step in the next batch process, the pressure in the storage tank 610 is reduced, thereby further reducing the possibility that the vaporized gas supplied into the process chamber 201 in the precursor gas supply step will contain mist or the like that may be generated due to incomplete vaporization of the liquid precursor.

### Other Embodiments of the Present Disclosure

The embodiments of the present disclosure have been specifically described above. However, the present disclosure is not limited to the above-described embodiments and may be modified in various ways without departing from the spirit and scope of the present disclosure.

In the above-described embodiment, the pressure in the storage tank 610 increases in step A of the liquid precursor replenishment process, and then the pressure is regulated in step B. However, the present disclosure is not limited thereto. For example, at least one selected from the group of the pressure and the supply flow rate of the liquid precursor supplied in step A may be adjusted to a value such that the pressure in the storage tank 610 at the end of step A is equal to or less than the saturated vapor pressure of the liquid precursor which is a predetermined pressure.

Specifically, the opening degree of the valve 720 in step A may be adjusted so that at least one selected from the group of the pumping pressure and the supply flow rate becomes the above-mentioned value. In addition, a liquid MFC may be further provided on the liquid supply pipe 754, and at least one selected from the group of the pumping pressure and the supply flow rate may be adjusted by controlling the liquid MFC.

In addition, at least one selected from the group of the pumping pressure and supply flow rate of the liquid precursor may be set to the above-mentioned value or less by providing an orifice portion (throttle portion) in the liquid supply pipe 754 or by providing a nozzle having a throttle portion at a tip of the liquid supply pipe 754.

In this way, by adjusting the pressure in the storage tank 610 at the end of step A to a value that is equal to or less than the saturated vapor pressure of the liquid precursor, it is possible to suppress the occurrence of incomplete vaporization caused by the increase in pressure in the storage tank 610, as in the above-described embodiment.

It is preferable that the recipe used for each process is prepared separately according to the processing contents and are recorded and stored in the memory 121c via an electric communication line or an external memory 123. When starting each process, it is preferable that the CPU 121a properly selects an appropriate recipe from a plurality of recipes recorded and stored in the memory 121c according to the process contents. This makes it possible to form films of various film types, composition ratios, film qualities and film thicknesses with high reproducibility in one substrate processing apparatus. In addition, the burden on an operator can be reduced, and each process can be quickly started while avoiding operation errors.

The above-described recipes are not limited to the newly prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. In addition, the input/output device 122 provided in the substrate existing processing apparatus may be operated to directly change the existing recipes already installed in the substrate processing apparatus.

In the above-described embodiment, there has been described the example in which a film is formed by using a batch type substrate processing apparatus for processing a plurality of substrates at a time. The present disclosure is not limited to the above-described embodiment, but may be suitably applied to, for example, a case where a film is formed using a single-substrate type substrate processing apparatus for processing one or several substrates at a time. Furthermore, in the above-described embodiment, there has been described the example in which a film is formed using a substrate processing apparatus having a hot wall type process furnace. The present disclosure is not limited to the above-described embodiment, but may also be suitably applied to a case where a film is formed using a substrate processing apparatus having a cold wall type process furnace.

Even when these substrate processing apparatuses are used, each process may be performed under the same processing procedures and processing conditions as those of the above-described embodiments and modifications. The same effects as those of the above-described embodiments and modifications may be obtained.

The above-described embodiments and modifications may be used in combination as appropriate. The processing procedure and processing conditions at this time may be, for example, the same as the processing procedures and processing conditions of the above-described embodiments and modifications.

According to the present disclosure, it is possible to suppress incomplete vaporization of the liquid precursor that may occur due to the injection of a liquid precursor into a vaporization container.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of controlling a vaporization system, comprising:
(a) supplying a liquid precursor into a vaporization container;
(b) regulating a pressure in the vaporization container to reduce the pressure at a time point when (a) is completed or after a first predetermined time has elapsed since the time point;
(c) after (b), maintaining a state in which the regulation of the pressure in the vaporization container is stopped while vaporizing the liquid precursor; and
(d) after (c), supplying a vaporized gas generated by vaporizing the liquid precursor in the vaporization container into a process container in which a substrate is processed.

2. The method of claim 1, further comprising: (e) between (c) and (d), regulating the pressure in the vaporization container to reduce the pressure.

3. The method of claim 2, wherein a time period for which pressure regulation is performed in (b) is longer than the time period for which pressure regulation is performed in (e).

4. The method of claim 2, wherein an exhaust speed of the vaporization container in (b) is lower than the exhaust speed of the vaporization container in (e).

5. The method of claim 2, further comprising: (f) between (e) and (d), maintaining a state in which the regulation of the pressure in the vaporization container is stopped.

6. The method of claim 1, wherein the supply of the vaporized gas into the process container is not performed from a start of (a) to a start of (d).

7. The method of claim 1, wherein in (b), the pressure in the vaporization container is regulated so that the pressure becomes less than a saturated vapor pressure of the liquid precursor in the vaporization container.

8. The method of claim 1, wherein in (b), the pressure is regulated until a second predetermined time has elapsed.

9. The method of claim 1, wherein in (b), the pressure in the vaporization container is regulated so that the pressure is reduced to a first predetermined pressure.

10. A method of manufacturing a semiconductor device, comprising the method of claim 1.

11. The method of claim 10, further comprising:
(e) before (d), loading the substrate into the process container; and
(f) after (d), unloading the substrate from the process container,
wherein for each time (e) and (f) are performed, (a), (b) and (c) are performed at least once.

12. The method of claim 10, further comprising:
(e) before (d), loading the substrate into the process container; and
(f) after (d), unloading the substrate from the process container,
wherein for each time (e) is performed multiple times and for each time (f) is performed multiple times, (a), (b) and (c) are performed at least once.

13. A vaporization system, comprising:
a vaporization container configured to vaporize a liquid precursor therein;
a liquid precursor supply system configured to supply the liquid precursor into the vaporization container;
a vaporized gas supply system configured to supply a vaporized gas generated by vaporization of the liquid precursor in the vaporization container into a process container in which a substrate is processed;
a pressure regulator configured to regulate a pressure in the vaporization container;
a heater configured to heat the liquid precursor in the vaporization container; and
a controller configured to control the liquid precursor supply system, the vaporized gas supply system, the pressure regulator, and the heater so as to execute:
(a) supplying the liquid precursor into the vaporization container;
(b) regulating a pressure in the vaporization container to reduce the pressure at a time point when (a) is completed or after a first predetermined time has elapsed since the time point;
(c) after (b), maintaining a state in which the regulation of the pressure in the vaporization container is stopped while vaporizing the liquid precursor; and
(d) after (c), supplying the vaporized gas into the process container.

14. The vaporization system of claim 13, wherein the pressure regulator includes an exhaust pipe having one end directly or indirectly connected to the vaporization container and the other end connected to an exhaust device, and a first valve installed on the exhaust pipe, and
wherein the controller is configured to reduce, in (b), the pressure in the vaporization container by controlling at least one selected from the group of opening/closing and an opening degree of the first valve.

15. The vaporization system of claim 14, wherein the pressure regulator further includes a flow rate controller installed on the exhaust pipe, and
wherein the controller is configured to adjust, in (b), the flow rate in the exhaust pipe by controlling the flow rate controller.

16. The vaporization system of claim 13, wherein the liquid precursor supply system includes a liquid precursor supply pipe having one end connected to the vaporization container and the other end connected to a supply source of the liquid precursor, and a second valve installed on the liquid precursor supply pipe, and
wherein the controller is configured to supply, in (a), the liquid precursor into the vaporization container by controlling at least one selected from the group of opening/closing and an opening degree of the second valve.

17. The vaporization system of claim 13, wherein the vaporized gas supply system includes a vaporized gas supply pipe having one end directly or indirectly connected to the vaporization container and the other end connected to the process container, and a third valve installed on the vaporized gas supply pipe, and
wherein the controller is configured to supply the vaporized gas from the vaporization container into the process container by controlling at least one selected from the group of opening/closing and an opening degree of the third valve.

18. The vaporization system of claim 13, wherein the liquid precursor supply system includes a liquid precursor supply pipe having one end connected to the vaporization container and the other end connected to a supply source of the liquid precursor, and wherein an orifice is provided in at least one selected from the group of an interior of the liquid precursor supply pipe and a tip of the one end of the liquid precursor supply pipe.

19. A substrate processing apparatus comprising the vaporization system of claim 13.

20. A non-transitory computer-readable recording medium storing a program that causes, by a computer, a substrate processing apparatus to perform a process comprising:
(a) supplying a liquid precursor into a vaporization container;
(b) regulating a pressure in the vaporization container to reduce the pressure at a time point when (a) is completed or after a first predetermined time has elapsed since the time point;
(c) after (b), maintaining a state in which the regulation of the pressure in the vaporization container is stopped while vaporizing the liquid precursor; and
(d) after (c), supplying a vaporized gas generated by vaporizing the liquid precursor in the vaporization container into a process container in which a substrate is processed.
